(19) United States
(12) Patent Application Publication
(10) Pub. No.: US 2013/0147485 A1
(43) Pub. Date: Jun. 13, 2013

(54) MAGNETIC RESONANCE IMAGING APPARATUS

(71) Applicant: Motohisa YOKOI, Nasushiobara-Shi (JP)

(72) Inventor: Motohisa YOKOI, Nasushiobara-Shi (JP)

(21) Appl. No.: 13/710,825

(22) Filed: Dec. 11, 2012

(30) Foreign Application Priority Data
Dec. 12, 2011 (JP) 2011-271570
Oct. 19, 2012 (JP) 2012-231931

(51) Int. Cl. G01R 33/385

(52) U.S. Cl. CPC G01R 33/385
USPC 324/318

(57) ABSTRACT

A magnetic resonance imaging apparatus includes a superconductive coil unit, a cooling vessel and a plurality of refrigerators. The superconductive coil unit includes a superconductive coil, and a supporter configured to support the superconductive coil. The cooling vessel houses the superconductive coil unit and is free from liquid helium. The plurality of refrigerators are disposed on the superconductive coil unit and cool the superconductive coil unit.

### CROSS-REFERENCE TO RELATED APPLICATION

This application is based upon and claims the benefit of priority from Japanese Patent Application No. 2011-271570, filed on Dec. 12, 2011, and Japanese Patent Application No. 2012-231931, filed on Oct. 19, 2012, the entire contents of all of which are incorporated herein by reference.

### FIELD

Embodiments of the present inventions relate to a magnetic resonance imaging (MRI: Magnetic Resonance Imaging) apparatus.

### BACKGROUND

Magnetic resonance imaging is an imaging method that magnetically excites a nuclear spin of an object placed in a static magnetic field with an RF signal of a Larmor frequency, and reconstructs an image from an MR signal which is generated with the excitation.

In an MRI apparatus, a superconductive magnet using immersion cooling by liquid helium is used. The superconductive magnet is structured to keep a superconducting state by immersing and cooling a superconductive coil in a helium vessel storing liquid helium.

However, helium is a rare substance, and therefore, a superconductive magnet which is capable of cooling the superconductive coil without using a large amount of liquid helium is required. Therefore, the prior art without using liquid helium is disclosed, which attaches an electronic cooling member onto a circumference of a superconductive coil, and cools the superconductive coil. However, the art cannot be said as sufficient to cool a super conductive coil. If cooling of the superconductive coil is insufficient, the risk of quench due to the factor such as external heat invasion increases.

The present embodiments are made in the light of the problem described above, and it is an object of the present embodiments to reduce a risk of quench without performing immersion cooling by liquid helium.

### BRIEF DESCRIPTION OF THE DRAWINGS

In accompanying drawings,

FIG. 1 is a schematic diagram showing a configuration of an MRI apparatus according to a first embodiment;

FIG. 2 is a view showing a cylindrical magnet in the MRI apparatus according to the first embodiment;

FIG. 3 is a diagram showing the configuration of a superconductive magnet unit in the MRI apparatus according to the first embodiment;

FIG. 4 is a view showing a first disposition example of a plurality of refrigerators;

FIG. 5 is a view showing a second disposition example of a plurality of refrigerators;

FIG. 6 is a view showing a third disposition example of a plurality of refrigerators;

FIG. 7 is a view showing a forth disposition example of a plurality of refrigerators;

FIG. 8 is a diagram showing the configuration of a superconductive magnet unit in an MRI apparatus according to a second embodiment; and

FIG. 9 is a diagram for explaining a process of exciting a superconductive coil.

### DETAILED DESCRIPTION

A magnetic resonance imaging (MRI) apparatus according to the present embodiments will be described with reference to the attached drawings.

To solve the above-described problems, the MRI apparatus according to the present embodiment includes: a superconductive coil unit configured to include a superconductive coil, and a supporter configured to support the superconductive coil; a cooling vessel configured to house the superconductive coil unit and to be free from liquid helium; and a plurality of refrigerators configured to be disposed on the superconductive coil unit and to cool the superconductive coil unit.

### First Embodiment

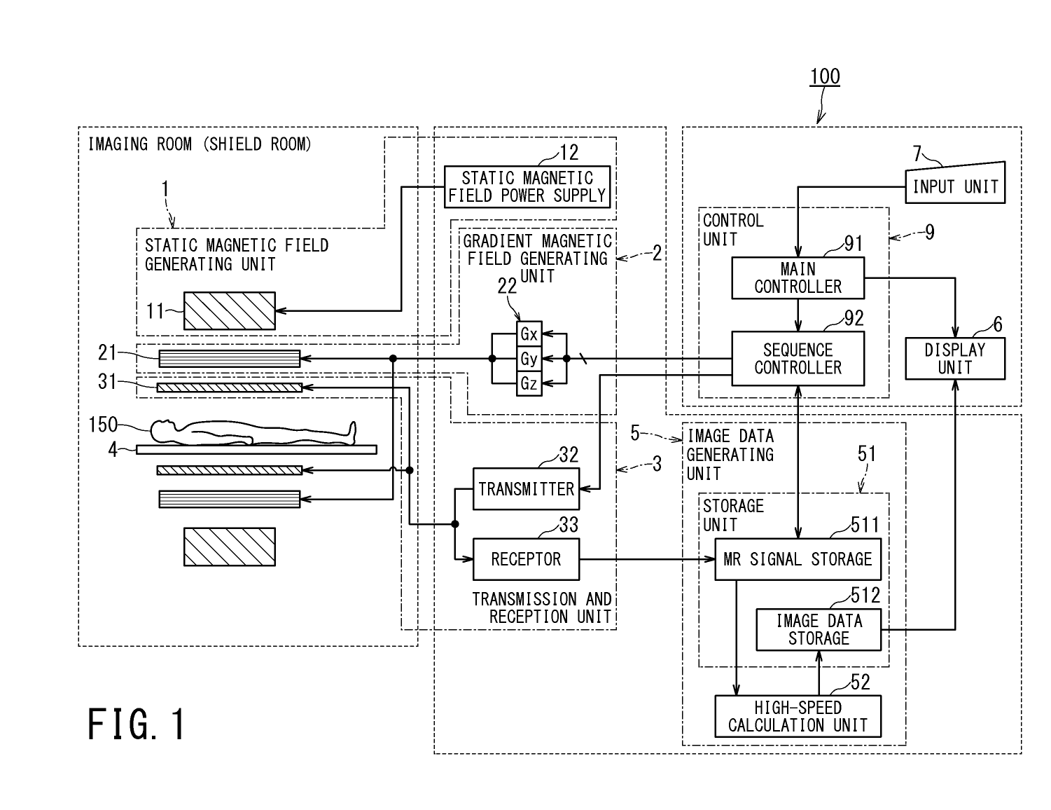

FIG. 1 is a schematic diagram showing a configuration of an MRI apparatus according to a first embodiment.

FIG. 1 shows an MRI apparatus 100 of the first embodiment. The MRI apparatus 100 includes a static magnetic field generating unit 1 and a gradient magnetic field generating unit 2 which generate magnetic fields to an object 150, a transmission and reception unit 3 that performs irradiation of RF pulse to the object 150 and reception of an MR signal, and a bed system 4 on which the object 150 is placed. Further, the MRI apparatus 100 includes an image data generating unit 5 that performs reconstruction processing of the MR signal received by the transmission and reception unit 3 and generates image data, a display unit 6 that displays the generated image data, an input unit 7 that performs setting of a collection condition of the MR signal and a display condition of the image data, input of various command signals and the like, and a control unit 9 that controls the respective units of the MRI apparatus 100.

The static magnetic field generating unit 1 includes a superconductive magnet unit 11, and a static magnetic field power supply 12 that supplies a current to the superconductive magnet unit 11, and forms a static magnetic field around the object 150.

The gradient magnetic field generating unit 2 includes gradient magnetic field coils 21 that form gradient magnetic fields in X, Y and X axes directions that are orthogonal to one another, and a gradient magnetic field power supply 22 that supplies a current to each of the gradient magnetic field coils 21.

The gradient magnetic field power supply 22 is supplied with a gradient magnetic field control signal by the control unit 9, and encoding of a space in which the object 150 is placed is performed. Namely, a pulse current which is supplied to the gradient magnetic field coils 21 in the X, Y and Z axes directions from the gradient magnetic field power supply 22 is controlled based on the above described gradient magnetic field control signal, whereby the gradient magnetic fields in the X, Y and Z axes directions are synthesized, and a slice selective gradient magnetic field Gs, a phase encoding gradient magnetic field Ge and a read-out field (frequency encoding) gradient magnetic field Gr which are orthogonal to one another are formed in optional directions. The gradient magnetic fields in the respective directions are superimposed on a static magnetic field formed by the superconductive magnet unit 11 to be applied to the object 150.

The transmission and reception unit 3 includes a transmission and reception coil 31 for irradiating the object 150 with an RF pulse and detecting an MR signal generated in the object 150, a transmitter 32 and a receptor 33 which are connected to the transmission and reception coil 31. Note that in the transmission and reception coil 31, a transmission coil and a reception coil may be provided by being separated from each other.

The transmitter 32 has a same frequency as a magnetic resonance frequency determined by the static magnetic field intensity of the superconductive magnet unit 11, drives the transmission and reception coil 31 by an RF pulse current modulated with a selective excitation waveform, and irradiates the object 150 with an RF pulse. Meanwhile, the receptor 33 performs signal processing such as A/D conversion for an electric signal which is received by the transmission and reception coil 31 as an MR signal, and temporarily stores the electric signal in an MR signal storage 511 as a digital signal.

A table-top included in the bed system 4 can move the object 150 to an optional position in a body axis direction in order to set a desired imaging position, and has a structure which can be inserted into an imaging space of a gantry. The superconductive magnet unit 11 of the static magnetic field generating unit 1, the gradient magnetic field coil 21 of the gradient magnetic field generating unit 2 and the transmission and reception coil 31 of the transmission and reception unit 3 are provided in the gantry, and are installed in an imaging room (shield room) together with the bed system 4.

The image data generating unit 5 includes a storage unit 51 and a high-speed calculation unit 52. The storage unit 51 includes an MR signal storage 511 that stores an MR signal, and an image data storage 512 that stores image data. The MR signal storage 511 stores the MR signal subjected to digital conversion by the receptor 33, and the image data storage 512 stores image data obtained by performing reconstruction processing of the aforementioned MR signal. The high-speed calculation unit 52 of the image data generating unit 5 performs image reconstruction processing by two-dimensional Fourier transformation for the MR signal which is temporarily stored in the MR signal storage 511, and generates image data of an actual space.

The display unit 6 includes a display data generating circuit, a conversion circuit and a monitor not illustrated. The display data generating circuit synthesizes the image data supplied from the image data storage 512 of the image data generating unit 5 and attendant information such as object information that is supplied from the input unit 7 via the control unit 9, and generates display data. The conversion circuit displays a video signal that is generated by converting the display data into a predetermined display format on a monitor configured by a CRT, liquid crystal or the like.

The input unit 7 includes various input devices such as a switch, a keyboard and a mouse and a display panel on a console, and performs input of object information, setting of a collection condition of the MR signal and a display condition of the image data, and input of a movement instruction signal of the bed system 4, an imaging start command signal and the like.

The control unit 9 includes a main controller 91 and a sequence controller 92. The main controller 91 is configured by a control circuit (first CPU), a storage circuit and the like not illustrated, and has a function of integratedly controlling the MRI apparatus 100. The storage circuit of the main controller 91 stores the object information, the collection condition of the MR signal, the display condition of the image data, information relating to an image display format and the like which are inputted or set in the input unit 7.

The first CPU of the main controller 91 generates pulse sequence information based on the aforementioned information inputted from the input unit 7 (for example, information concerning magnitudes, application times, application timing and the like of the pulse currents which are applied to the gradient magnetic field coil 21 and the transmission and reception coil 31) and supplies the pulse sequence information to the sequence controller 92.

The sequence controller 92 of the control unit 9 includes a control circuit (second CPU) and a storage circuit not illustrated, and after the sequence controller 92 temporarily stores the pulse sequence information sent from the main controller 91 in the aforementioned storage circuit, the sequence controller 92 controls the gradient magnetic field power supply 22 of the gradient magnetic field generating unit 2 and the transmitter 32 and the receptor 33 of the transmission and reception unit 3 in accordance with the pulse sequence information.

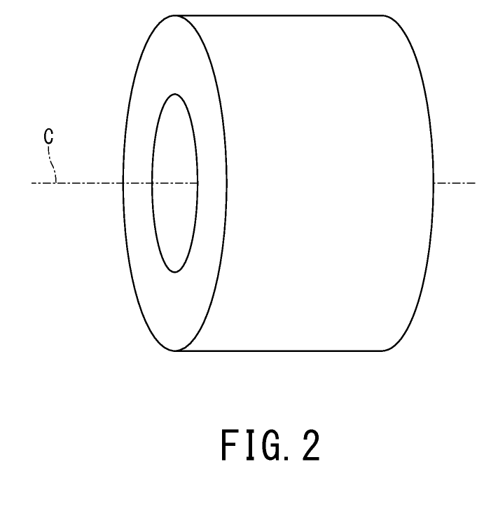

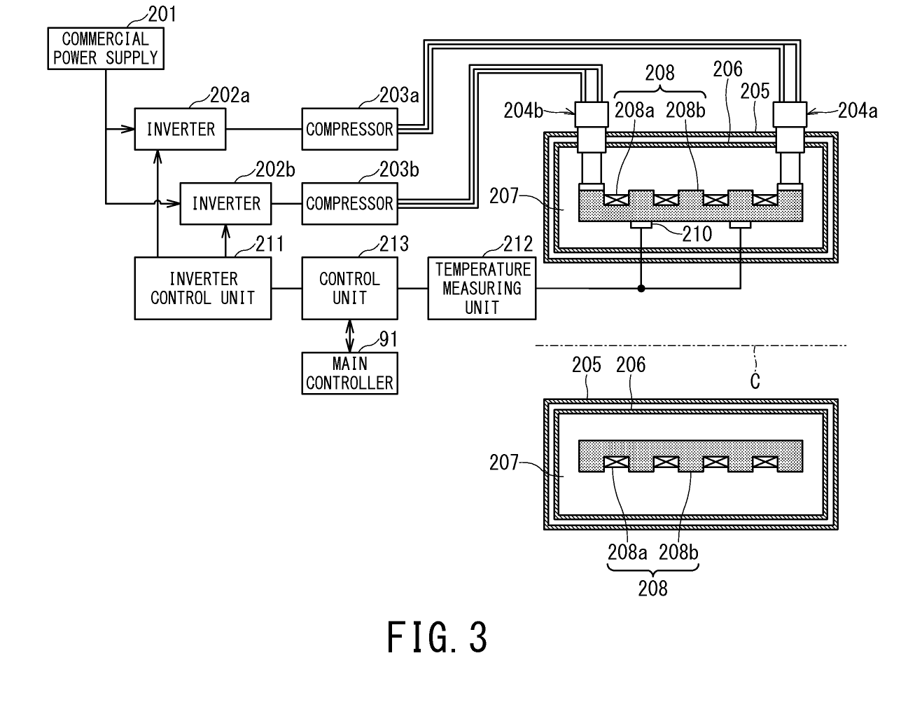

Next, a configuration of the superconductive magnet unit 11 will be described with use of FIGS. 2 and 3. Here, the superconductive magnet unit 11 using a cylindrical magnet will be described as an example.

FIG. 2 is a view showing a cylindrical magnet in the MRI apparatus according to the first embodiment. FIG. 3 is a diagram showing the configuration of the superconductive magnet unit 11 in the MRI apparatus according to the first embodiment.

As for the magnet of the superconductive magnet unit 11 shown in FIG. 3, the cylindrical magnet of FIG. 2 is shown along a vertical section with a center axis C of a cylinder being vertical. As shown in FIG. 3, when the cylindrical magnet is used as the magnet, the magnet is symmetrical with respect to the center axis C of the cylinder except for installation portions of refrigerators.

The magnet of the superconductive magnet unit 11 includes a plurality of refrigerators (compact cryogenic refrigerators: cold heads) 204a and 204b, a vacuum vessel 205, a heat shield 206, a cooling vessel 207, a superconductive coil unit 208, and a temperature sensor 210. In FIG. 3, the two refrigerators 204a and 204b are shown as the refrigerators, but the number of refrigerators is not limited to this, and may be three or more.

The super conductive coil unit 208 includes a superconductive coil 208a and a bobbin (supporter) 208b. A groove for winding the superconductive coil 208a is provided on an outer periphery of the bobbin 208b. The superconductive coil 208a is disposed on the bobbin 208b via the groove.

The refrigerators 204a and 204b are disposed on the superconductive coil unit 208 inside the cooling vessel 207. As shown in, for example, FIG. 3, the refrigerators 204a and 204b are disposed on the bobbin 208b of the superconductive coil unit 208. The refrigerators 204a and 204b expand a compressed refrigerant gas (a helium gas, a nitrogen gas and the like) to generate cold to cool the bobbin 208b directly, and thereby cool the superconductive coil 208a disposed on the bobbin 208b.

Alternatively, each of the refrigerators 204a and 204b may be disposed on the superconductive coil 208a, though not illustrated. In that case, each of the refrigerators 204a and 204b expands the compressed refrigerant gas to generate cold and directly cools the superconductive coil 208a. Of course, each of the refrigerators 204a and 204b may be disposed astride the superconductive coil 208a and the bobbin 208b, though not illustrated.

Note that the inverter, the compressor and the cold head are entirely called “refrigerator” in some cases, but in the present embodiment, only the cold head is called “refrigerator”.

The cooling vessel 207 is provided in the vacuum vessel 205 configured to shut off external heat, and has an interior thereof maintained under vacuum. That is to say, the cooling vessel 207 is configured without liquid helium. The cooling vessel 207 has the heat shield 206 to enhance a thermal insulation effect.

The heat shield 206 is preferably configured by a plurality of layers (usually, two layers or three layers).

At least one temperature sensor 210 is provided on the superconductive coil unit 208 (the superconductive coil 208a or the bobbin 208b). In the example shown in FIG. 2, a temperature measuring unit 212 is connected to the temperature sensor 210, and obtains a temperature of the superconductive coil unit 208 from a measurement value of the temperature sensor 210.

Note that the vacuum vessel 205 at a lower side of FIG. 3 is a lower side section of the cylindrical magnet, and has a structure which is symmetrical around the center axis except for the refrigerators 204a and 204b.

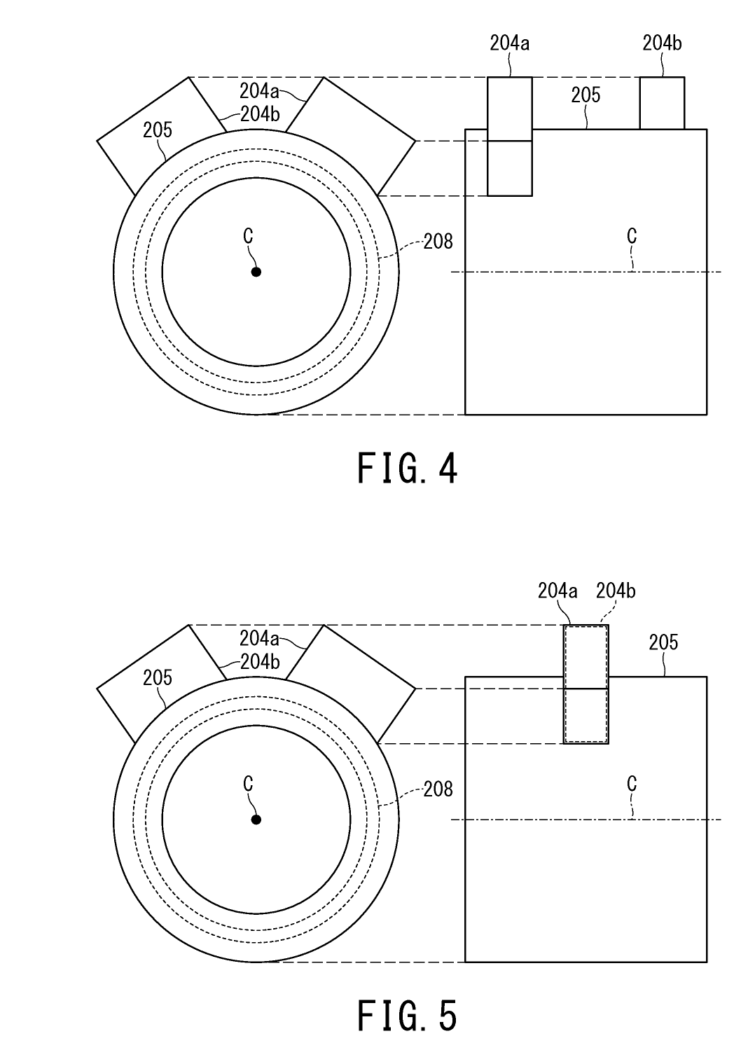

FIGS. 4 to 7 are views showing disposition examples of a plurality of refrigerators.

Left sides of FIGS. 4 to 7 each show a front surface (surface at a side in which the object 150 is inserted) of the cylindrical magnet of FIG. 2. Right sides of FIGS. 4 to 7 each show a side surface of the cylindrical magnet of FIG. 2.

In the disposition example shown in FIG. 4, the plurality of refrigerators 204a and 204b are disposed at random on the side surface of the cylindrical magnet.

In the disposition example shown in FIG. 5, the plurality of refrigerators 204a and 204b are disposed by being arranged on a circumference of the cylindrical magnet.

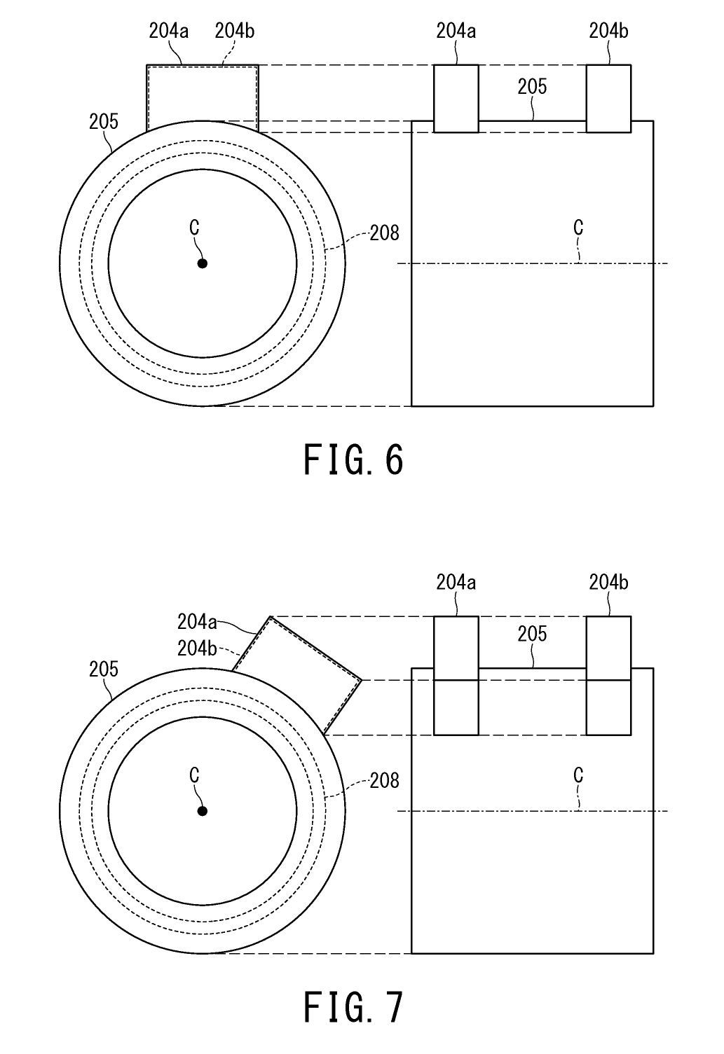

In the disposition examples shown in FIGS. 6 and 7, the plurality of refrigerators 204a and 204b are disposed by being arranged on a straight line parallel with an advancing and retracting direction (center axis C) of the bed system 4. Further, when three or more refrigerators are included, the refrigerators are similarly disposed by being arranged on a straight line parallel with the center axis C.

In the disposition example shown in FIG. 6, the refrigerators 204a and 204b which are respectively inserted toward the superconductive coil unit 208 from directly above the vacuum vessel 205 are disposed by being arranged side by side. In the disposition example shown in FIG. 7, the refrigerators 204a and 204b which are inserted respectively toward the superconductive coil unit 208 from diagonally above the vacuum vessel 205 are disposed by being arranged side by side.

Disposition of the refrigerators 204a and 204b in the MRI apparatus 100 may be any one of FIGS. 4 to 7. However, in each of the disposition examples shown in FIGS. 6 and 7, the refrigerator 204b at a rear side is hidden behind the refrigerator 204a at a front side when the magnet is seen from the front surface, and therefore, the magnet looks small. Consequently, according to the disposition examples shown in FIGS. 6 and 7, an effect of suppressing a sense of pressure of the object 150 that is inserted into a bore while seeing the front surface of the magnet is generated.

Returning to the description of FIG. 3, the refrigerators 204a and 204b respectively include supply pipes for supplying a high-pressure refrigerant gas from compressors 203a and 203b. The refrigerators 204a and 204b respectively include discharge pipes for discharging the gas which is expanded inside the refrigerators 204a and 204b to the compressors 203a and 203b.

The compressors 203a and 203b are connected to inverters 202a and 202b, respectively. The inverters 202a and 202b each include a converter circuit, a smoothing circuit and an inverter circuit. The inverters 202a and 202b are connected to a commercial power supply 201, and after the inverters 202a and 202b convert an AC voltage of the commercial power supply 201 into a DC voltage in the converter circuits, the inverters 202a and 202b smooth the DC voltage in the smoothing circuits, and converts the DC voltage into an AC voltage of an optional frequency in the inverter circuits.

An inverter control unit 211 is connected to the temperature measuring unit 212. The inverter control unit 211 controls the inverters 202a and 202b so that the temperature of the superconductive coil 208 becomes a set temperature, based on a temperature of the superconductive coil unit 208 (the superconductive coil 208a or the bobbin 208b) measured in the temperature measuring unit 212.

Conventionally, there has been conduction cooling which cools by using a substance with a high thermal conductivity, besides cooling by liquid helium. When the superconductive coil is cooled by conduction cooling, a structure is such that one refrigerator cools all the superconductive coils, and therefore, if the refrigerator stops due to failure of the refrigerator, power failure or the like, the temperature of the magnet coils rises due to heat invasion from an outside. When the temperature of the magnet coil reaches a superconductive critical temperature of the super conductive coil, the superconductive magnet cannot retain a superconducting state, and there arises the fear of a phenomenon in which energy stored in the superconductive coils is released at a dash (generally called quench).

When quench occurs, the energy stored in the superconductive coils, that is, energy of about several to several tens megajoules is released as heat. When abrupt heat occurs to the superconductive coils, abrupt thermal stress occurs to a superconductive coil main body and the bobbin that holds it, and may cause damage to the superconductive magnet. Further, for the purpose of recooling that removes heat which is generated inside, a great deal of time (usually, several weeks) is required.

In the refrigerators, wear parts are present structurally, and therefore, regular maintenance is also required. In this case, the refrigerators need to be stopped temporarily, and temporary reduction of a magnetic field (demagnetization) and re-excitation after maintenance are required so that quench does not occur for the above described reason. An excitation/demagnetization operation of a magnet has a high risk of quench, and therefore, a mechanism that reduces the times of the operation as much as possible is demanded.

In the first embodiment, a plurality of refrigerators (two or more) are used. Thereby, even if at least one of the refrigerators fails, the refrigerator is switched to at least one of the remaining refrigerators, whereby occurrence of quench can be suppressed. With reference to FIG. 3, a process of switching a plurality of refrigerators will be described.

(First operation example in a plurality of refrigerators)

The case in which the refrigerator 204a fails (performance degradation) when out of the plurality of refrigerators 204a and 204b, the refrigerator 204a is in use, and the refrigerator 204b is not in use will be described as an example.

If the refrigerator 204a fails, a temperature of the superconductive coil unit 208 rises. When the temperature measured in the temperature measuring unit 212 rises by a predetermined temperature or more from a set temperature, the control unit 213 determines that a cooling ability of the refrigerator 204a has declined. When the control unit 213 determines that the cooling ability of the refrigerator 204a has declined, the control unit 213 stops supply of the commercial power supply 201 to the inverter 202a through the inverter control unit 211, and starts supply of the commercial power supply 201 to the inverter 202b. When supply of the commercial power supply 201 is stopped, the inverter 202a stops supply of an AC voltage to the compressor 203a. As a result, the compressor 203a stops, and use of the refrigerator 204a stops.

When supply of the commercial power supply 201 is started, the inverter 202b starts supply of an AC voltage to the compressor 203b. As a result, the compressor 203b operates, and use of the refrigerator 204b starts.

As above, when at least one of a plurality of refrigerators fails, the refrigerator is switched to at least one of the remaining refrigerators, whereby occurrence of quench can be suppressed.

When the refrigerator stops, heat invasion from the outside becomes large, and therefore, at least one of the refrigerators is desired to have a variable cooling ability. More desirably, a cooling ability of at least one of the refrigerators is preferably set to be higher than a required cooling ability (for example, approximately 110%). The cooling ability of the refrigerator can be changed by changing the frequency of the AC voltage which is given to the compressor from the inverter. More specifically, if the frequency of the AC voltage given to the compressor is made high, the rotational frequency of the motor of the compressor rises, and the cooling ability becomes high. In contrast with this, if the frequency of the AC voltage given to the compressor is made low, the rotational frequency of the motor of the compressor decreases, and the cooling ability declines.

(Second operation example in a plurality of refrigerators)

The case in which maintenance of the refrigerator 204a is performed when out of the plurality of refrigerators 204a and 204b, the refrigerator 204a is in use, and the refrigerator 204b is not in use will be described as an example.

In this case, as described in the first operation example, by switching the refrigerator to be stopped to the remaining refrigerator, maintenance can be performed without reducing the magnetic field (demagnetization). Thereby, a demagnetization/excitation operation is not required, and the risk of quench can be reduced.

In the system described above, it is important that even if at least one refrigerator stops, sufficient cooling performance is maintained by another refrigerator. Therefore, it is important to inform, in advance, an operator or the like that the performance of the refrigerator has declined and maintenance is required. With reference to FIG. 3, a method thereof will be described.

The inverter 202a, the compressor 203a and the refrigerator 204a (hereinafter, they will be collectively called “group ‘a’”), and the inverter 202b, the compressor 203b and the refrigerator 204b (hereinafter, they will be collectively called “group ‘b’”) are switched to be operated at each set time (for example, a day to a week or the like).

There is no problem unless a temperature of the superconductive coil unit 208 at a time of an operation of the group ‘a’, and a temperature of the superconductive coil unit 208 measured in the temperature measuring unit 212 at a time of an operation of the group ‘b’ both become abnormal. However, if the temperature of the superconductive coil unit 208 which is measured in the temperature measuring unit 212 during operation of one of the groups shows a high tendency as compared with another group, it is determined that the group with the temperature increased degrades in performance and needs maintenance. The operator or the like is notified of the content through the system control section 91 from the control unit 213. When the performance of some groups degrades, the cooling performance is kept in other groups. Further, when the performance degrades in the two groups or more, the control unit 213 controls so that the two or more groups keep the cooling ability in such a manner as to complement the performance with each other.

As above, according to the MRI apparatus 100 of the first embodiment, in the case in which the cooling vessel 207 has a configuration without liquid helium, the risk of occurrence of quench can be suppressed by cooling of the superconductive coil unit 208 by a plurality of refrigerators. More specifically, according to the MRI apparatus 100 of the first embodiment, even if the operation of at least one refrigerator out of a plurality of refrigerators is stopped, the risk of occurrence of quench can be suppressed by switching the refrigerator to at least one of the remaining refrigerators.

### Second Embodiment

A schematic diagram of a configuration of an MRI apparatus according to a second embodiment is similar to the schematic diagram showing the configuration of the MRI apparatus according to the first embodiment shown in FIG. 1, and therefore, the description thereof will be omitted.

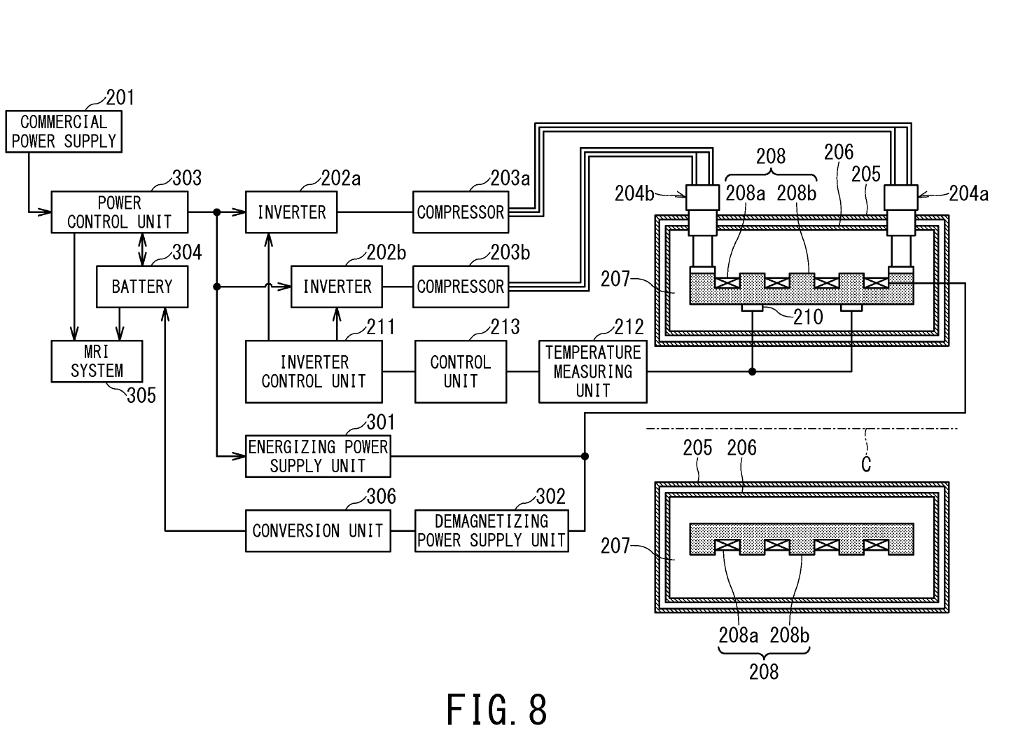

FIG. 8 is a diagram showing the configuration of the superconductive magnet unit in the MRI apparatus according to the second embodiment.

As for respective sections of the second embodiment shown in FIG. 8, the sections similar to the superconductive magnet unit 11 of FIG. 3 are shown by the same reference signs. The second embodiment differs from the first embodiment in that even if power is not supplied from the commercial power supply 201 such as mains power due to power failure or the like, the superconductive magnet unit 11 can continuously operate a refrigerator by using energy stored in a battery 304. A capacity of the battery 304 desirably corresponds to energy stored in the superconductive coil 208a or more. Though the battery is not especially limited, an industrial battery may be used, or an electric automobile battery (for example, a capacity of approximately 10 MJ or more) may be used.

Here, a process of exciting the superconductive coil 208a will be described.

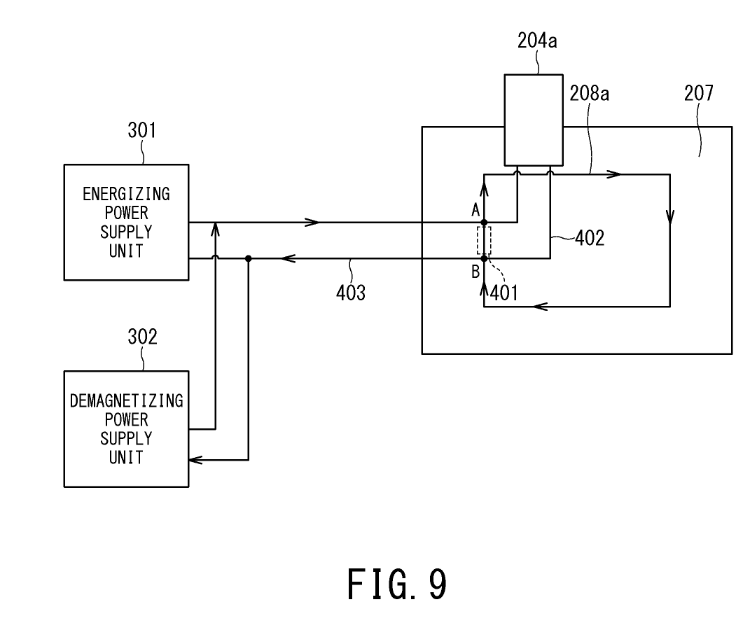

FIG. 9 is a diagram for explaining the process of exciting the superconductive coil 208a.

FIG. 9 shows the refrigerator 204a, the cooling vessel 207, the superconductive coil 208a, an energizing power supply unit 301, a demagnetizing power supply unit 302, a switch heater 401, a connection section 402, and a wire rod 403.

FIG. 9 shows only the refrigerator 204a for simplification of illustration, but the same thing also applies to other refrigerators. The demagnetizing power supply unit 302 is electrically cut off.

First, the switch heater 401 installed between A and B shown in FIG. 9 is turned on. Thereupon, the temperature between A and B rises, and a superconducting state is changed to a normal conducting state, whereby between A and B, a voltage is generated and a predetermined current flows. The current flowing between A and B passes through a superconductive portion between A and B, and energy is accumulated in the superconductive coil 208a. When the current flowing between A and B reaches a predetermined current value which is set to be lower than a critical current, the switch heater 401 is turned off.

Next, in order to cool a region between A and B, heat of the heater between A and B is released by thermal conduction by using the connection section 402 which is connected to the refrigerator 204a and has a high thermal conductivity. When the region between A and B is cooled, and the superconducting state is brought about, a current which flows via the energizing power supply unit 301 is brought into a state in which the current flows between A and B, and a permanent current mode is brought about. When the permanent current mode is brought about, the current which is passed from the energizing power supply unit 301 is shut off.

In order to release the heat of the heater between A and B by thermal conduction as above, a cooling structure around the switch heater 401 needs to be reinforced. As the cooling structure like this, for example, the wire rod 403 which connects the superconductive coil 208a and the energizing power supply unit 301 can be made a superconductive wire rod. Thereby, after the switch heater 401 is turned off, the switch heater 401 is efficiently cooled, and the superconductive coil 208a can be easily shifted to the permanent current mode.

Next, a demagnetizing method will be described. In FIG. 9, an output terminal of the energizing power supply unit 301 is electrically cut off. First, a same current as the current which flows into the superconductive magnet is passed to the demagnetizing power supply unit 302 in an arrow direction. Thereafter, the switch heater 401 is turned on, and the superconducting state between the A and B is shifted to the normal conducting state. A current route thereafter is the demagnetizing power supply unit 302 to an A point to the superconductive coil 208a to a B point to the demagnetizing power supply unit 302. The current gradually decreases by decreasing the output voltage of the demagnetizing power supply unit 302 to a minus voltage, and all the magnetic fields are ultimately eliminated. At this time, seen from the demagnetizing power supply unit 302, the plus current is passed to the minus output voltage, and therefore, the energy inside the magnet is taken to the outside. The energy is usually consumed in an external heat generating element as thermal energy.

Returning to the description of FIG. 8, a power control unit 303 is a control circuit that controls power of the respective units and sections of the MRI apparatus 100. The power control unit 303 is connected to the commercial power supply 201, and supplies the power supplied from the commercial power supply 201 to the battery 304, the inverters 202a and 202b, the inverter control unit 211 and an MRI system 305 (configuration other than the superconductive magnet unit 11 of the MRI apparatus 100).

At a time of normal use, the power control unit 303 charges the battery 304 so that a remaining amount of the energy stored in the battery 304 becomes a predetermined value (for example, 90% or more of a maximum capacity).

At a time of power failure, the power control unit 303 switches the power supply source to the battery 304 from the commercial power supply 201, and stops the MRI system 305. In this case, the power control unit 303 desirably displays the remaining amount of the energy stored in the battery 304 on a monitor not illustrated. The power control unit 303 operates the demagnetizing power supply unit 302 and a conversion unit (voltage conversion unit) 306 at a time point at which the remaining amount of the battery 304 does not exceed 100% of the maximum capacity even if the energy stored in the superconductive coil 208a is regenerated. Next, the demagnetizing power supply unit 302 regenerates the energy stored in the superconductive coil 208a into the battery 304 through the conversion unit 306.

A regeneration principle is according to the following. That is, the energy which is conventionally consumed as thermal energy is charged into the battery 304 directly as electric energy instead of heat. Regenerative electromotive force which is generated at the time of normal demagnetization and a charging voltage of the battery 304 differ from each other. Therefore, the regenerative electromotive force which is generated from the magnet is temporarily passed through the conversion unit 306 and is converted into a charging voltage of the battery 304 to charge the battery 304. Meanwhile, the power control unit 303 continues to supply power to the inverters 202a and 202b and the inverter control unit 211 by using the energy stored in the battery 304. The demagnetizing power supply unit 302 regenerates the energy of the superconductive coil 208a and can perform operation until the remainder energy remaining amount of the superconductive coil 208a is reduced to zero. Furthermore, the refrigerator can be operated until the energy stored in the battery is used up, and therefore, in the case in which power failure or the like lasts for a long period of time, the superconductive coil can be kept cooled.

As above, according to the MRI apparatus 100 of the second embodiment, in addition to the effect of the MRI apparatus 100 of the first embodiment, the refrigerator can be continuously operated by using the energy stored in the battery, even if the power is not supplied from the commercial power supply due to power failure or the like. Further, when the remaining amount of the battery is reduced to a predetermined amount or less, electric energy is regenerated into the battery by performing the demagnetizing process, whereby heat generation of the superconductive magnet due to quench can be prevented. Furthermore, by the energy of the battery that is regenerated, the refrigerator can be operated for a longer period of time.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus, comprising:
a superconductive coil unit configured to include a superconductive coil, and a supporter configured to support the superconductive coil;
a cooling vessel configured to house the superconductive coil unit and to be free from liquid helium; and
a plurality of refrigerators configured to be disposed on the superconductive coil unit and to cool the superconductive coil unit.

2. The magnetic resonance imaging apparatus according to claim 1,
wherein each of the plurality of refrigerators is a cold head that generates cold by expanding a compressed refrigerant gas.

3. The magnetic resonance imaging apparatus according to claim 1,
wherein the plurality of refrigerators are disposed on a bobbin of the superconductive coil unit.

4. The magnetic resonance imaging apparatus according to claim 1,
wherein the plurality of refrigerators are disposed by being arranged on one straight line parallel with an advancing and retracting direction of a bed system on which an object is placed.

5. The magnetic resonance imaging apparatus according to claim 1,
wherein an inside of the cooling vessel is under vacuum.

6. The magnetic resonance imaging apparatus according to claim 1, further comprising:
a temperature sensor configured to be disposed on the superconductive coil unit, and to detect a temperature of the superconductive coil unit; and
a control unit configured to switch an operation to a remaining refrigerator of the plurality of refrigerators, upon determining that a cooling ability of at least one refrigerator has declined based on the detected temperature, during operation of at least the one refrigerator of the plurality of refrigerators.

7. The magnetic resonance imaging apparatus according to claim 6,
wherein when at least the one refrigerator and the remaining refrigerator are alternately operated, and when a temperature during operation of at least the one refrigerator shows a high tendency as compared with a temperature during operation of the remaining refrigerator, the control unit determines that the cooling ability of at least the one refrigerator has declined.

8. The magnetic resonance imaging apparatus according to claim 6,
wherein at least one of the plurality of refrigerators has a variable cooling ability.

9. The magnetic resonance imaging apparatus according to claim 6,
wherein the control unit reports that the cooling ability of at least the one refrigerator has declined.

10. The magnetic resonance imaging apparatus according to claim 1, further comprising:
a power control unit configured to be connected to a power supply; and
a battery configured to be connected to the power control unit,
wherein the power control unit switches a power supply source to the battery from the power supply.

11. The magnetic resonance imaging apparatus according to claim 10, further comprising:
a demagnetizing power supply unit configured to regenerate energy stored in the superconductive coil to the battery.

12. The magnetic resonance imaging apparatus according to claim 11,
wherein the demagnetizing power supply unit regenerates the energy stored in the superconductive coil to the battery when a remaining amount of the battery becomes a predetermined amount or less.
